(19) United States
(12) Patent Application Publication
(10) Pub. No.: US 2012/0037407 A1
(43) Pub. Date: Feb. 16, 2012

(54) Electronic Apparatus and Method of Manufacturing the Same

(76) Inventors: Tadahiro Ohmi, Miyagi (JP); Hirokazu Asahara, Miyagi (JP); Kohei Watanuki, Miyagi (JP); Kouji Tanaka, Miyagi (JP)

(21) Appl. No.: 13/266,269

(22) PCT Filed: Apr. 10, 2010
(86) PCT No.: PCT/JP2010/056531

§ 371 Date: Oct. 26, 2011

(30) Foreign Application Priority Data
Apr. 28, 2009 (JP) 2009-109552

(51) Int. Cl. H05K 1/03; C23C 16/50; B32B 17/06; C23C 16/40

(52) U.S. Cl. 174/255; 427/576

(57) ABSTRACT

It has been found out that, among transparent conductive layers, a zinc oxide layer has a function of preventing diffusion of sodium. An electronic apparatus is obtained which uses the zinc oxide layer as an electrode of the electronic apparatus and also as a diffusion preventing layer for preventing diffusion of sodium from a glass substrate.

### TECHNICAL FIELD

This invention relates to an electronic apparatus, such as a solar cell or a large-size display having a glass substrate, and to a method of manufacturing the same.

### BACKGROUND ART

In an electronic apparatus, such as a solar cell or a large-size flat panel display apparatus, a glass substrate is generally used. An inexpensive glass substrate, such as a soda glass, contains sodium. If an electronic element, such as a solar cell element, a display element, or a switching element, is formed on the glass substrate of the type, sodium in the glass substrate diffuses into the electronic element to degrade the characteristics of the electronic element. Therefore, the glass containing sodium has not been used to form a long-life high-performance electronic apparatus and an expensive non-alkali glass free of sodium has normally been used.

In the meanwhile, with the increase in size of the electronic apparatuses, the glass substrate is increased in area. As a consequence, the glass substrate itself is increased in cost. Under the circumstances, it has been strongly desired to use an inexpensive glass substrate in order to reduce the cost of the large-size electronic apparatuses.

In order to use the inexpensive glass substrate containing sodium, it is known to form a sodium diffusion preventing layer thereon (Patent Document 1).

### PRIOR ART DOCUMENT

### Patent Document:

Patent Document 1: JP-A-2000-243327

### SUMMARY OF THE INVENTION

### Problem to be Solved by the Invention:

However, Patent Document 1 discloses a method of forming, as the sodium diffusion preventing layer, a silica film, a phosphorus-doped silica film, a silicon oxynitride film, a silicon nitride film, and so on to a thickness of 500 nm by sputtering or the like. If the method is applied to a large-size substrate, the cost is increased and the effect of preventing sodium diffusion is not high.

On the other hand, some of the present inventors have proposed, as a sodium diffusion preventing layer which is easily and inexpensively applicable to a large-size glass substrate and which exhibits a high sodium diffusion preventing effect, a sodium diffusion preventing layer formed of a planarization coating film. On such a sodium diffusion preventing layer, an electronic element layer is formed via a transparent conductive film to construct an electronic apparatus. However, formation of the sodium diffusion preventing layer itself causes an increase in number of process steps and an increase in cost. Hence, further improvement is desired.

It is therefore an object of the present invention to obtain an electronic apparatus which can be more inexpensively manufactured using a glass substrate containing alkali metal, such as sodium, and a method of manufacturing the same.

### Means to Solve the Problem:

Conventionally, in an electronic apparatus in which an electronic element is formed on an alkali glass base member, a transparent electrode layer for the electronic element is formed on a sodium diffusion preventing layer of the alkali glass base member. On the other hand, the present inventors have newly found that, when a zinc oxide layer is used as the transparent electrode, the zinc oxide layer itself functions as an excellent diffusion preventing layer with respect to alkali metal, such as sodium. As a result, they have found a fact that, only by using the zinc oxide layer, the conventional sodium diffusion preventing layer can be omitted, and reached the present invention.

Therefore, according to the present invention, it is possible to obtain an apparatus, namely, an electronic apparatus which uses a zinc oxide layer as a transparent electrode and as an alkali metal diffusion preventing layer.

Specifically, according to an aspect of the present invention, an electronic apparatus is obtained. The electronic apparatus comprises a glass base member containing sodium and a zinc oxide layer formed on a surface of the glass base member. An electronic element is formed on the zinc oxide layer. In this case, the zinc oxide layer is a sodium diffusion preventing layer and functions as a transparent electrode of the electronic element.

It is desirable that the zinc oxide layer is doped with Ga, Al, or In.

According to another aspect of the present invention, a method of manufacturing an electronic apparatus is obtained. The method includes a step of forming a zinc oxide layer on at least one principal surface of a glass base member containing sodium by plasma CVD using an organometallic material.

According to a further aspect of the present invention, an alkali metal diffusion preventing method that prevents diffusion of alkali metal using a transparent conductive layer is obtained. Herein, the transparent conductive layer is a zinc oxide layer and the alkali metal is sodium.

It is desirable that the zinc oxide layer is that was formed on a glass substrate containing sodium as the alkali metal by plasma CVD using an organometallic material.

### Effect of the Invention:

According to the present invention, an electrode, which is easily and inexpensively applicable to a large-size glass substrate and which constructs an electronic apparatus, is formed by a material having a sodium diffusion preventing effect. With the above-mentioned structure, it is possible to provide an electronic apparatus which does not require a sodium diffusion preventing layer to be separately provided and a method of manufacturing the same.

### BRIEF DESCRIPTION OF THE DRAWING

FIG. 1 is a schematic illustrative view of a plasma processing apparatus used when a zinc oxide layer (ZnO layer) is prepared according to a first embodiment of the present invention.

FIG. 2 shows views for describing SIMS analysis results of a sodium diffusion preventing performance of the ZnO layer in each of the first embodiment according to the present invention and a comparative example.

FIG. 3 is a schematic sectional view for describing a structure of a photoelectric conversion element and a solar cell according to a second embodiment of the present invention.

FIG. 4A is a view for describing, in the order of steps, a manufacturing process of the photoelectric conversion element shown in FIG. 3.

FIG. 4B is a view for describing, in the order of steps, the manufacturing process of the photoelectric conversion element shown in FIG. 3.

FIG. 4C is a view for describing, in the order of steps, the manufacturing process of the photoelectric conversion element shown in FIG. 3.

FIG. 4D is a view for describing, in the order of steps, the manufacturing process of the photoelectric conversion element shown in FIG. 3.

FIG. 4E is a view for describing, in the order of steps, the manufacturing process of the photoelectric conversion element shown in FIG. 3.

FIG. 4F is a view for describing, in the order of steps, the manufacturing process of the photoelectric conversion element shown in FIG. 3.

FIG. 4G is a view for describing, in the order of steps, the manufacturing process of the photoelectric conversion element shown in FIG. 3.

FIG. 4H is a view for describing, in the order of steps, the manufacturing process of the photoelectric conversion element shown in FIG. 3.

FIG. 5 is a schematic sectional view showing a structure when the present invention is applied to a display element.

### MODES FOR CARRYING OUT THE INVENTION

Hereinbelow, embodiments of the present invention will be described with reference to the drawings.

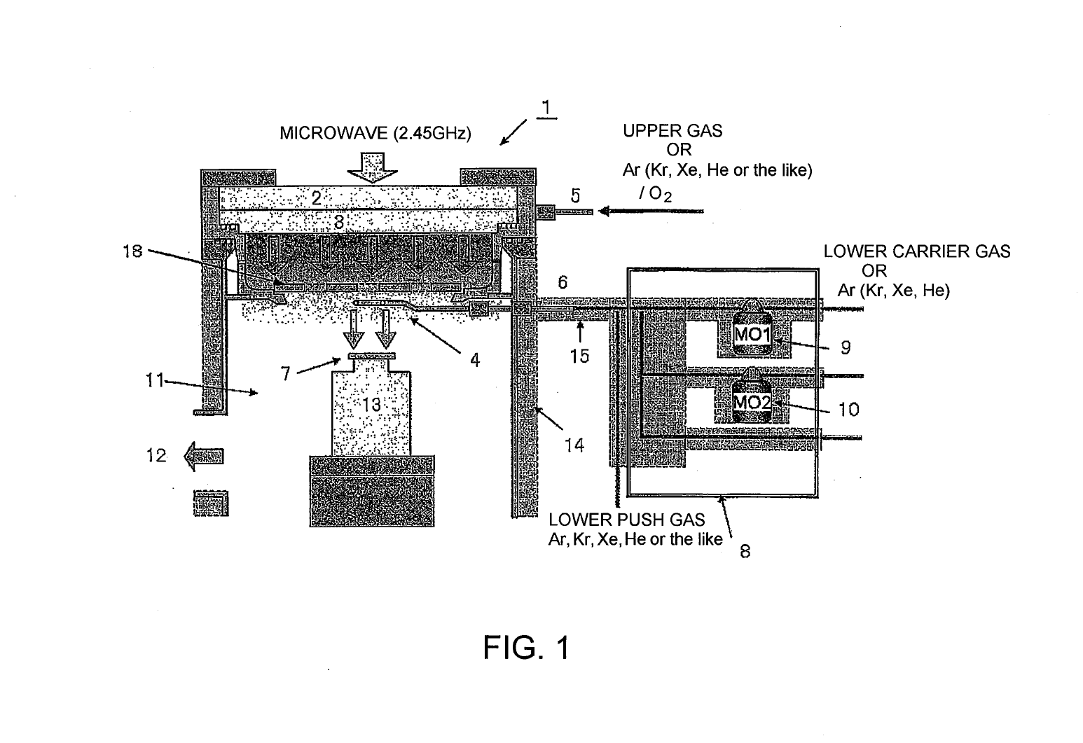

FIG. 1 is a schematic sectional view showing a plasma processing apparatus used to form a zinc oxide (ZnO) layer according to a first embodiment of the present invention. The plasma processing apparatus 1 shown in the figure is a microwave-excited high-density plasma processing apparatus and has a process chamber 11. The process chamber 11 is provided therein with a dielectric top plate 2, a dielectric upper shower plate 3, a lower shower nozzle 4, and a stage 13. On the stage 13, a soda glass substrate 7 containing Na is placed. Slightly above the lower shower nozzle 4, a partition plate 18 with one or more openings is installed.

Herein, a microwave is transmitted through the dielectric top plate 2 and the dielectric upper shower plate 3 and radiated to a plasma generation region in an upper part of the process chamber 11 of the plasma processing apparatus 1. A plasma excitation gas is supplied through a gas introduction pipe 5 to the upper shower plate 3 and uniformly ejected from the upper shower plate 3 over the plasma generation region. In the present embodiment, an Ar gas is used as the plasma excitation gas. Alternatively, a Kr gas, a Xe gas, or a He gas may be used.

As described above, the microwave is radiated to the plasma generation region formed between the upper shower plate 3 and the partition plate 18. By the microwave, a plasma is excited in the plasma excitation gas. The plasma is introduced from the plasma generation region into a diffusion plasma region and to the lower shower nozzle 4 installed in the diffusion plasma region.

Herein, the above-mentioned plasma excitation gas and an O₂ gas (reactive gas) are introduced through the gas introduction pipe 5 into the upper shower plate 3. On the other hand, a gas of an organometallic material is supplied from a gas introduction pipe 6 to the lower shower nozzle 4. Thus, a compound thin film can be formed on a surface of the substrate 7.

The plasma processing apparatus 1 illustrated in the figure has an organometallic material supply system 8 for supplying an organometallic material for forming a ZnO layer. In the organometallic material supply system 8, two organometallic material (MO) containers 9 and 10 are provided. The organometallic material is delivered from these MO containers 9 and 10 through the gas introduction pipe 6 to the lower shower nozzle 4.

An exhaust gas in the process chamber 11 passes through an exhaust duct via an exhaust system 12 (only an exhaust port is shown with illustration of an exhaust structure being omitted) to be introduced into a small-size exhaust pump (not shown in the figure).

The process chamber 11 illustrated in the figure has a diameter of 240 mm and is provided therein with the stage 13 for placing the substrate 7 of a 33 mm-square rectangular soda (Na) glass thereon. The stage 13 illustrated in the figure is movable upward and downward by a motor drive so that the substrate 7 can be arranged at a height of an optimal position. The stage 13 is provided inside with a structure which has a build-in heater (not shown in the figure) for heating the substrate 7 so as to control its temperature to a desired temperature.

A wall surface of the plasma processing apparatus 1 shown in FIG. 1 is temperature-controlled by a heater 14 to, for example, 100° C. for the purpose of suppressing adhesion of reaction products. Further, a gas pipe extending from the organometallic material supply system 8 to the lower shower nozzle 4 is temperature-controlled by a heater 15 to a temperature not lower than that of each of the material containers.

The top plate 2 installed in the upper part of the process chamber 11 has a diameter of 251 mm and a thickness of 15 mm and the upper shower plate 3 has a diameter of 251 mm and a thickness of 30 mm. The top plate 2 and the upper shower plate 3 are both made of an alumina ceramic material.

A lower surface of an end portion of the lower shower nozzle 4 is provided with a plurality of small holes for uniformly ejecting a gas. Each of the holes has a diameter of 0.5 mm or 0.7 mm. The end portion of the lower shower nozzle has a ring shape with an outer diameter of 33 mm and an inner diameter of 17 mm.

In a film forming process of the zinc oxide (ZnO) layer according to the present embodiment, the ZnO layer is formed on the substrate 7 by using an organometallic material containing Zn and an Ar plasma with O₂ added thereto. Instead of the Ar plasma, Kr, Xe, or He may be used. Specifically, as the organometallic material containing Zn, DMZ (dimethylzinc) was used in the present embodiment but DEZ (diethylzinc) may be used. The organometallic material of Zn is kept in the organometallic material container (MO1) represented by the reference numeral 9 and delivered to the lower shower nozzle 4 by a carrier gas, such as Ar.

Further, in the present embodiment, a Ga-doped ZnO (i.e. GZO) film was formed. For this purpose, an organometallic material containing Ga was kept in the organometallic material container (MO2) represented by 10 and delivered by the carrier gas, such as Ar, to the lower shower nozzle 4 together with the Zn material gas. As the organometallic material of Ga, Ga(CH₃)₃, i.e. TMG (trimethylgallium) was used but Ga(C₂H₅)₃, i.e. TEG (triethylgallium) may be used.

In the present embodiment, an Ar gas and O₂ were supplied through the gas introduction pipe 5 to the upper shower plate 3 by 200 cc per minute and by 100 cc per minute, respectively. The organometallic gas containing Zn and Ga (DMZ of 0.2 cc per minute, TMG of 5%, and Ar gas of 180 cc) was supplied through the gas introduction pipe 6 to the lower shower nozzle 4.

On the other hand, the substrate 7 of Na glass was kept at a stage temperature of 400° C., the process chamber 11 was kept at a pressure of 0.1 Torr, and a microwave of 1500 w was introduced. Then, film formation was performed for 10 minutes. As a consequence, a GZO layer (Ga-doped ZnO layer) was formed on the glass substrate 7 to a thickness of 260 nm. It is noted here that TMG of 5% means an amount such that TMG/(DMZ+TMG) is 5% in volume. Instead of Ga, Al, In, or the like may be doped into the zinc oxide (ZnO) layer. Depending on the type of an electronic apparatus, non-doped layer may be used.

Herein, in order to verify a sodium diffusion preventing effect of the above-mentioned GZO layer, a comparative example was prepared in which a glass substrate 7 was made of a non-alkali glass and a GZO film was formed thereon in a manner similar to that mentioned above.

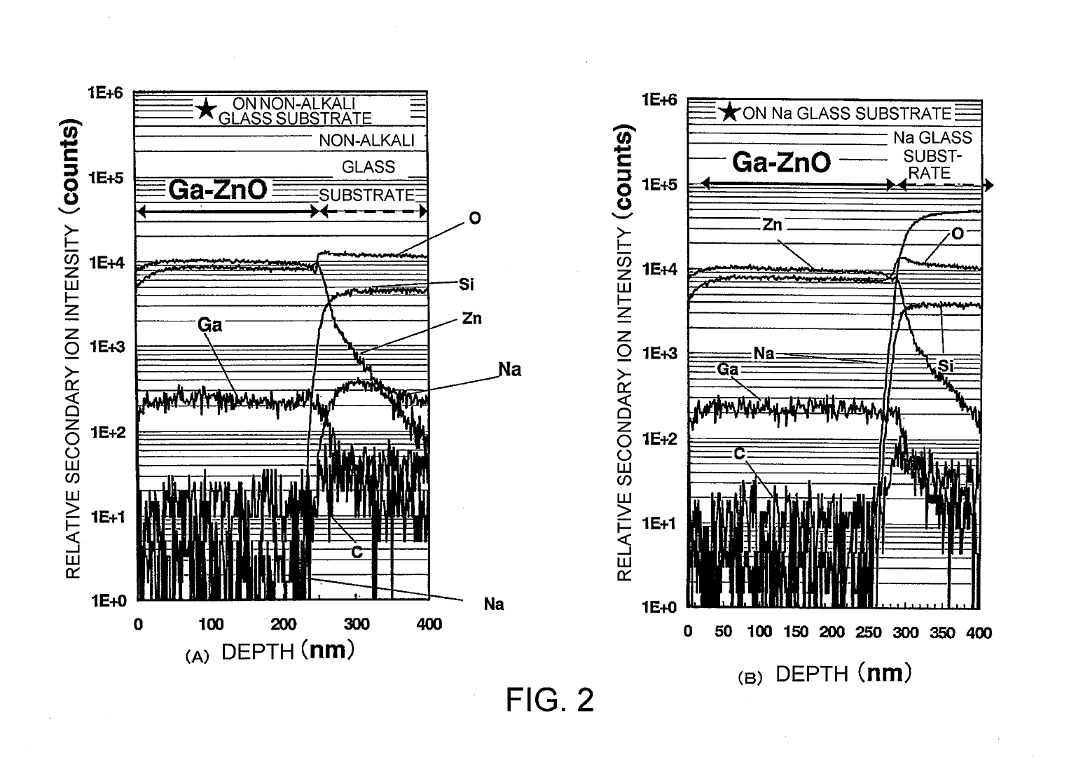

Referring to FIG. 2, SIMS (Secondary Ionization Mass Spectrometer) analysis results on sodium diffusion preventing performances of the ZnO layers formed as described above are shown. Curved lines illustrated in the figure represent respective components contained in the ZnO layers and the glass substrates.

FIG. 2 (A) shows a case where the ZnO layer having a thickness of 260 nm is formed on the non-alkali glass substrate. It is understood that the non-alkali glass substrate contains a large amount of oxygen (O) and silicon (Si), while the GZO layer contains a large amount of zinc (Zn) and gallium (Ga) in addition to oxygen (O). Further, it is understood that sodium (Na) on the order of about 1E+2 is contained in the non-alkali glass substrate but the amount of sodium (Na) is decreased to the order of 1E+1 or less in the GZO layer.

On the other hand, as shown in FIG. 2 (B), the Na glass substrate containing sodium (Na) of 1E+4 or more contains oxygen (O) and silicon (Si) to the same extent as the non-alkali glass. It is understood that Ga and Zn are contained in the GZO layer formed on the Na glass substrate but the amount of sodium (Na) contained therein is decreased to 1E+1 or less.

As described above, the amount of sodium diffused from the non-alkali glass substrate into the ZnO (GZO in this example) layer is extremely small. Also in the embodiment of the present invention where the ZnO (GZO) layer is formed on the Na glass substrate, the amount of Na in the ZnO film is as extremely small as that of Na in the ZnO layer on the non-alkali glass substrate. This means that diffusion of sodium from the Na glass substrate can be prevented.

It is obvious from FIG. 2 that diffusion of sodium (Na) can substantially be suppressed if the ZnO layer has a thickness of 150 nm or more.

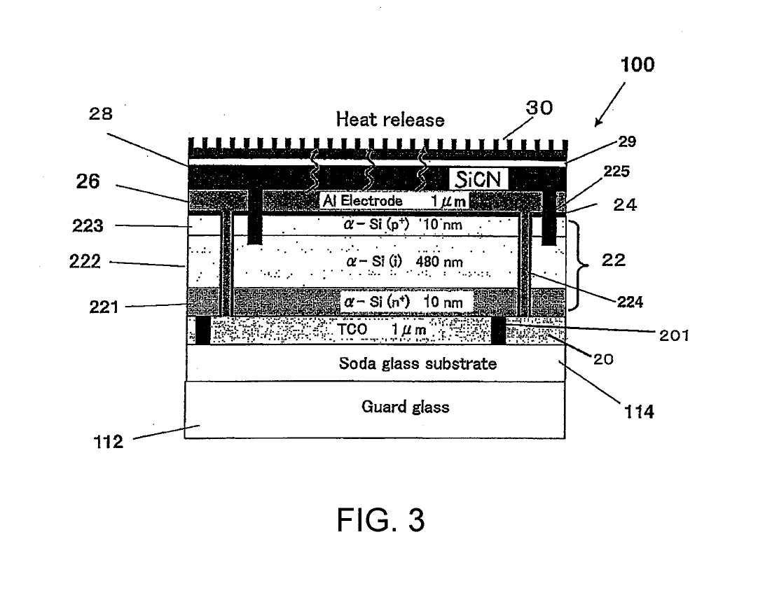

Next, referring to FIG. 3, a photoelectric conversion element 100 according to a second embodiment of the present invention will be described. The photoelectric conversion element 100 illustrated in the figure is formed on a base member including a guard glass 112 and a glass substrate 114 attached to the guard glass 112. The illustrated glass substrate 114 is formed of an inexpensive soda glass containing Na. For the purpose of preventing contamination of the element due to diffusion of Na from the soda glass, a sodium barrier layer is conventionally formed between the photoelectric conversion element 100 and the glass substrate 114. However, in the present invention, without forming the sodium barrier layer, a transparent electrode layer (transparent conductive layer) as a first electrode 20 is directly formed on the glass substrate 114. As apparent from the figure, the photoelectric conversion element 100 to become a unit cell is electrically connected in series to other adjacent photoelectric conversion elements (cells) to construct a solar cell.

Specifically, the photoelectric conversion element 100 according to the embodiment of the present invention has the first electrode 20, a power generation laminate 22 formed of a-Si (amorphous silicon) and having a nip structure, and an Al second electrode layer 26 formed on the power generation laminate 22 through a selenium layer 24.

The first electrode 20 constructing the photoelectric conversion element 100 is a transparent conductor electrode (Transparent Conductive Oxide (TCO) layer) and, herein, is formed of a ZnO layer having a film thickness of 1 μm. The ZnO layer (first electrode) 20 is a Ga-doped n⁺-type ZnO layer. The n⁺-type ZnO layer constructing the first electrode 20 is provided with insulating films 201 (herein, SiCN) formed at predetermined intervals and is divided and sectionalized cell by cell.

On the first electrode 20, an n⁺-type a-Si layer 221 constructing a part of the power generation laminate 22 is formed. The n⁺-type a-Si layer 221 is brought into contact with the transparent electrode constructing the first electrode 20. The illustrated n⁺-type a-Si layer 221 has a film thickness of 10 nm. On the n⁺-type a-Si layer 221, an i-type a-Si layer 222 and a p-type a-Si layer 223 constructing the power generation laminate 22 are successively formed.

The i-type a-Si layer 222 and the p-type a-Si layer 223 illustrated in the figure have film thicknesses of 480 nm and 10 nm, respectively. The n⁺-type a-Si layer 221, the i-type a-Si layer 222, and the p⁺-type a-Si layer 223 constructing the power generation laminate 22 illustrated in the figure are provided with via holes 224 formed at positions different from those of the insulating layers 201 of the first electrode 20. Each of the via holes has an inner wall provided with a SiO₂ layer formed thereon.

The power generation laminate 22 of a nip structure has a thickness of 500 nm in total and thus has a thickness of 1/100 or less as compared to a photoelectric conversion element formed of monocrystalline or polycrystalline silicon.

Next, on the p-type a-Si layer 223, the second electrode layer 26 is formed through the selenium (Se) layer 24. The second electrode layer 26 is formed of Al which is formed also inside the via holes 224 (the inner walls being insulated with SiO₂) of the power generation laminate 22. Al inside the via holes 224 is electrically connected to the adjacent first electrode 20 of the photoelectric conversion element. The selenium (Se) layer 24 constructing a contacting portion between the second electrode layer and the p-type a-Si layer is used because Se has a work function (−6.0 eV) which is close to that of the p-type a-Si layer. The selenium layer may be replaced with Pt (−5.7 eV) which is similarly close in work function.

Further, on the second electrode layer 26, a passivation film 28 of SiCN is formed. An insulating material (herein, SiCN) forming the passivation film 28 is also buried in holes 225 which pass through the second electrode layer 26, the selenium layer 24, and the p-type a-Si layer 223 to reach the i-type a-Si layer 222. On the passivation film 28, a heat sink 30 (formed of, for example, Al) is mounted through an adhesive layer 29 formed of a material excellent in thermal conductivity.

The ZnO layer forming the first electrode 20 may be doped with Al, In, or the like instead of Ga to thereby form the n⁺-type ZnO layer.

With the photoelectric conversion element 100 illustrated in FIG. 3, an energy conversion efficiency of about 20% was obtained by a single cell of the photoelectric conversion element 100. When a solar cell module having a size of 1.15 m×1.40 m is constructed by connecting the photoelectric conversion elements 100, an electric power of 307 W was obtained and an energy conversion efficiency of the module was 18.9%.

In the structure shown in FIG. 3, the n-type amorphous silicon (a-Si) layer and the n-type ZnO layer obtained by adding Ga to ZnO are joined to each other. This results in a structure in which electrons easily flow from the n-type amorphous silicon (a-Si) layer to the n-type ZnO layer. Specifically, when the n-type amorphous silicon (a-Si) layer and the n-type ZnO layer (herein, n⁺-type ZnO layer) are joined to each other, a bandgap between a conduction band Ec and a valence band Ev of the a-Si layer is 1.75 eV. On the other hand, a conduction band Ec of the n⁺-type ZnO layer is lower than the conduction band Ec of the a-Si layer by 0.2 eV and is lower than a Fermi level Ef. Therefore, there is substantially no electronic barrier between the conduction band Ec of the a-Si layer and the conduction band Ec of the n⁺-type ZnO layer. Consequently, electrons flow from the conduction band Ec of the a-Si layer into the conduction band Ec of the n⁺-type ZnO layer with high efficiency. As described above, since there is substantially no barrier between the a-Si layer and the n⁺-type ZnO layer, it is possible to efficiently move the electrons from the a-Si layer to the n⁺-type ZnO layer. Thus, when the photoelectric conversion element is constructed, it is possible to flow a high current, thereby improving an energy efficiency.

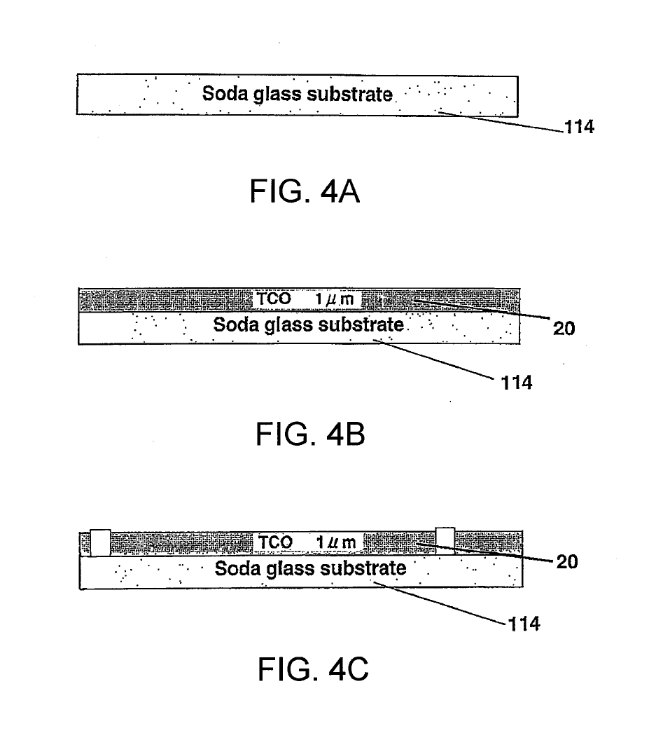

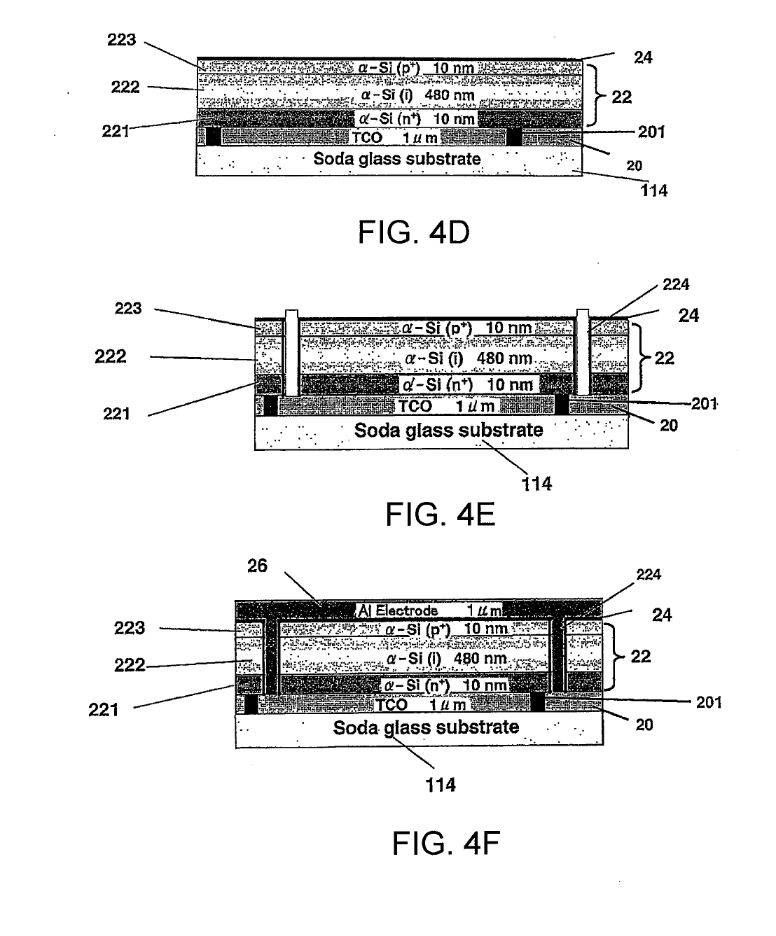

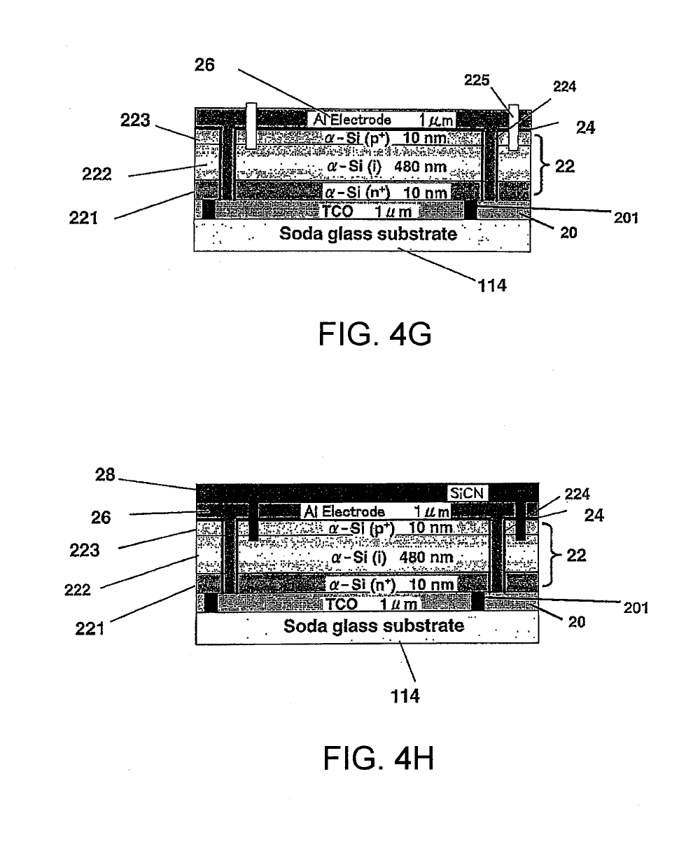

Hereinbelow, referring to FIG. 4, a method of manufacturing the photoelectric conversion element 100 illustrated in FIG. 3 and a solar cell will be described. In this example, description will be made about a case where MSEP (Metal Surface-wave Excited Plasma) type plasma processing apparatuses (with or without a lower gas nozzle or a lower gas shower plate) described in International Publication having International Publication No. WO2008/153064 are used as first to eighth plasma processing apparatuses.

As shown in FIG. 4A, the glass substrate 114 formed of soda glass is first prepared.

Next, as shown in FIG. 4B, the glass substrate 114 is introduced into the first plasma processing apparatus provided with the lower gas nozzle or the lower gas shower plate and a transparent electrode (TCO layer) having a thickness of 1 μm is formed as the first electrode 20. In the first plasma processing apparatus, the n⁺-type ZnO layer is formed by doping Ga. The Ga-doped n⁺-type ZnO layer is formed as follows. In the first plasma processing apparatus, a mixed gas of Kr and O₂ is supplied from the upper gas nozzle to the chamber to generate a plasma and a mixed gas of Ar, Zn(CH₃)₂, and Ga(CH₃)₃ is ejected from the lower gas nozzle or the lower gas shower plate into the plasma generated in an atmosphere containing Kr and oxygen. As a consequence, the n⁺-type ZnO layer (first electrode) 20 is formed on the glass substrate 114 by plasma CVD.

Subsequently, on the n⁺-type ZnO layer as the first electrode 20, a photoresist is applied. Thereafter, the photoresist is patterned by using a photolithography technique. After the photoresist is patterned, the glass substrate is introduced into the second plasma processing apparatus provided with the lower gas nozzle or the lower gas shower plate. In the second plasma processing apparatus, using the patterned photoresist as a mask, the n⁺-type ZnO layer is selectively etched to form, in the n⁺-type ZnO layer (first electrode) 20, openings reaching the glass substrate 114 as shown in FIG. 4C.

The etching in the second plasma processing apparatus is performed by supplying an Ar gas from the upper gas nozzle to the chamber and supplying, into a plasma generated in an Ar atmosphere, a mixed gas of Ar, Cl₂, and HBr supplied from the lower gas nozzle or the lower gas shower plate to the chamber.

The glass substrate 114 provided with the n⁺-type ZnO layer having the openings and the photoresist applied onto the n⁺-type ZnO layer is conveyed to the third plasma processing apparatus without the lower gas nozzle or the lower gas shower plate. In the third plasma processing apparatus, the photoresist is removed by ashing in a Kr/O₂ plasma atmosphere.

After the photoresist is removed, the glass substrate 114 to which the n⁺-type ZnO layer 20 having the openings is adhered is introduced into the fourth plasma processing apparatus provided with the lower gas nozzle or the lower gas shower plate.

In the fourth plasma processing apparatus, SiCN as the insulating film 201 is first formed in the openings and on a surface of the n⁺-type ZnO layer 20 by plasma CVD. Thereafter, SiCN on the surface of the n⁺-type ZnO layer 20 is removed by etching in the same fourth plasma processing apparatus. As a result, the insulating film 201 is buried only in the openings of the n⁺ ZnO layer 20. The film formation of SiCN in the fourth plasma processing apparatus is performed by supplying Xe and NH₃ gases from the upper gas nozzle into the chamber to generate a plasma and introducing a mixed gas of Ar, SiH₄, and SiH(CH₃)₃ from the lower gas nozzle or the lower gas shower plate into the chamber to carry out CVD film formation. Next, in the same chamber, introduced gases are changed. An Ar gas is supplied from the upper gas nozzle into the chamber to generate a plasma and a mixed gas of Ar and CF₄ is introduced from the lower gas nozzle or the lower gas shower plate into the chamber to remove SiCN on the surface of the n⁺-type ZnO layer 20 by etching.

Subsequently, in the same fourth plasma processing apparatus, the introduced gases are sequentially changed. Thus, the power generation laminate 22 having a nip structure and the Se layer 24 are formed by continuous CVD.

As shown in FIG. 4D, in the fourth plasma processing apparatus, the n⁺-type a-Si layer 221, the i-type a-Si layer 222, the p⁺-type a-Si layer 223, and the selenium (Se) layer 24 are sequentially formed.

Specifically, in the fourth plasma processing apparatus, a mixed gas of Ar and H₂ is supplied from the upper gas nozzle to the chamber to generate a plasma and a mixed gas of Ar, SiH₄, and PH₃ is introduced from the lower gas nozzle or the lower gas shower plate into the chamber to form the n⁺-type a-Si layer 221 by plasma CVD. Next, the mixed gas of Ar and H₂ is continuously supplied from the upper gas nozzle to the chamber to generate a plasma, while the gas from the lower gas nozzle or the lower gas shower plate is changed from the Ar, SiH₄, and PH₃ gas to an Ar+SiH₄ gas and introduced. Thus, the i-type a-Si layer 222 is formed. Further, the mixed gas of Ar and H₂ is continuously supplied from the upper gas nozzle to the chamber to generate a plasma, while the gas from the lower gas nozzle or the lower gas shower plate is changed from the Ar and SiH₄ gas to an Ar+SiH₄+B₂H₆ gas. Thus, the p⁺-type a-Si layer 223 is formed. Next, the mixed gas of Ar and H₂ is continuously supplied from the upper gas nozzle to the chamber to generate a plasma, while the gas from the lower gas nozzle or the lower gas shower plate is changed from the Ar, SiH₄, B₂H₆ gas to a mixed gas of Ar and H₂Se. Thus, the selenium layer 24 is formed by CVD.

As described above, in the same MSEP type plasma processing apparatus, the introduced gases are sequentially changed so that the six layers are formed and etched. Therefore, it is possible to form an excellent film with less defects and, at the same time, to substantially reduce a manufacturing cost.

The glass substrate 114 with the selenium layer 24 and the power generation laminate 22 mounted thereon is introduced from the fourth plasma processing apparatus into a photoresist coater (slit coater) and applied with a photoresist. Thereafter, the photoresist is patterned by a photolithography technique.

After the photoresist is patterned, the glass substrate 114 with the selenium layer 24 and the power generation laminate 22 mounted thereon is introduced, together with the patterned photoresist, into the fifth plasma processing apparatus provided with the lower gas nozzle or the lower gas shower plate. In the fifth plasma processing apparatus, the selenium layer 24 and the power generation laminate 22 are selectively etched using the photoresist as a mask to form the via holes 224 reaching the first electrode 20 as shown in FIG. 4E. That is, the four layers are sequentially etched in the fifth plasma processing apparatus.

By etching in the fifth plasma processing apparatus, the glass substrate 114 is provided with the via holes 224 which penetrate from the selenium layer 24 to the first electrode (n⁺-type ZnO layer) 20 to reach the first electrode 20. The glass substrate is transferred from the fifth plasma processing apparatus to the above-mentioned third plasma processing apparatus without the lower gas nozzle or the lower gas shower plate. Then, the photoresist is removed by ashing in the plasma generated in the atmosphere of the Kr/O₂ gas introduced from the upper gas nozzle into the chamber.

The glass substrate 114 after the photoresist is removed is transferred to the sixth plasma processing apparatus provided with the lower gas nozzle or the lower gas shower plate. As shown in FIG. 4F, the Al layer having a thickness of 1 μm is formed as the second electrode layer 26 on the selenium layer 24. The Al layer is formed also in the via holes 224. Formation of the Al layer is performed by supplying a mixed gas of Ar and H₂ from the upper gas nozzle to the chamber to generate a plasma, while an Ar+Al(CH₃)₃ gas is ejected from the lower gas nozzle or the lower gas shower plate into the plasma generated in an Ar/H₂ atmosphere.

Subsequently, on the Al layer as the second electrode layer 26, a photoresist is applied. Thereafter, patterning is performed. Then, the glass substrate is introduced into the seventh plasma processing apparatus provided with the lower gas nozzle or the lower gas shower plate.

In the seventh plasma processing apparatus, an Ar gas is supplied from the upper gas nozzle to the chamber to generate a plasma, while an Ar+Cl₂ gas is ejected from the lower gas nozzle or the lower gas shower plate into the plasma generated in an Ar atmosphere to etch the Al layer. In the seventh plasma processing apparatus, subsequently, a mixed gas of Ar and H₂ is supplied from the upper gas nozzle to the chamber to generate a plasma, while an Ar+CH₄ gas is introduced from the lower gas nozzle or the lower gas shower plate into the plasma generated in an Ar/H₂ atmosphere to etch the selenium layer 24. In the seventh plasma processing apparatus, next, an Ar gas is supplied from the upper gas nozzle to the chamber to generate a plasma, while the gas from the lower gas nozzle or the lower gas shower plate is changed to an Ar+HBr gas to etch the p⁺-type a-Si layer 223 and a part of the i-type a-Si layer 222 to its middle.

As a result, as shown in FIG. 4G, the holes 225 are formed which extend from a surface of the Al layer 26 and reach the middle of the i-type a-Si layer 222. Also in this process, using the same MSEP type plasma processing apparatus and by sequentially changing gases, the four layers are consecutively etched. Therefore, substantial reduction in processing time and cost are achieved.

Next, the glass substrate 114 with the element illustrated in FIG. 4G mounted thereon is transferred to the above-mentioned third plasma processing apparatus without the lower gas nozzle or the lower gas shower plate. Then, the photoresist is removed by ashing by the plasma generated in an atmosphere of a Kr/O₂ gas introduced from the upper gas nozzle into the chamber.

The glass substrate 114 including, as the second electrode layer 26, the Al layer from which the photoresist is removed is introduced into the eighth plasma processing apparatus provided with the lower gas nozzle or the lower gas shower plate. Then, a SiCN film is formed by CVD to form the insulating layer (passivation film) 28 on the Al layer 26 and in the holes 225. Thus, the photoelectric conversion element and the solar cell as desired are manufactured as shown in FIG. 4H.

In the manufacturing method described above, the same plasma processing apparatuses can be used for formation of a plurality of layers and so on. Therefore, it is possible to manufacture a photoelectric conversion element and a solar cell in a state where contamination due to oxygen in the atmosphere, impurities, or the like is removed.

In the foregoing, the present invention has been described with reference to the preferred embodiments. However, the present invention is not limited to the embodiments described above. Within the spirit and the scope of the present invention described in the claims, the structure and the details of the present invention may be modified in various manners which can be understood by persons skilled in the art. For example, in the embodiments described above, description has been made about only a case where the power generation laminate having a nip structure is entirely formed of the a-Si layers. However, the i-type a-Si layer may be replaced by crystalline silicon or microcrystalline amorphous silicon. Further, another or more power generation laminates may be deposited on the power generation laminate 22.

### INDUSTRIAL APPLICABILITY

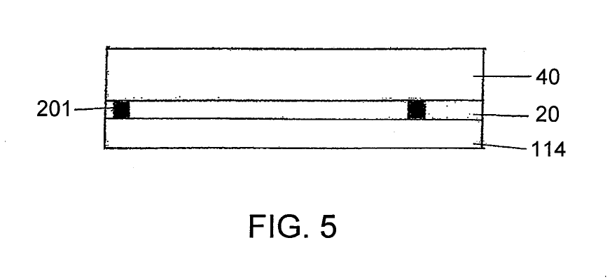

In the foregoing, taking the solar cell as one example of the electronic element, the structure of the present invention has been described. However, the present invention is applicable to a display element 40 and other electronic elements formed on the first electrode (zinc oxide layer) 20 formed on the glass substrate 114 as shown in FIG. 5. The above-mentioned zinc oxide layer can be used as a sodium diffusion preventing layer and simultaneously as a transparent electrode of an electronic element. Further, the present invention is highly effective also as an alkali metal diffusion preventing method which is used in order to utilize a transparent conductive layer constructing an electronic apparatus in preventing diffusion of not only sodium but also other alkali metal, such as potassium. Furthermore, the present invention is possibly applicable not only to the zinc oxide layer but also to other materials (for example, In) forming a transparent electrode.

1. An electronic apparatus comprising a glass base member containing sodium and a zinc oxide layer formed on a surface of the glass base member, an electronic element being formed on the zinc oxide layer.

2. The electronic apparatus as claimed in claim 1, wherein the zinc oxide layer is a sodium diffusion preventing layer and functions as a transparent electrode of the electronic element.

3. The electronic apparatus as claimed in claim 1, wherein the zinc oxide layer is doped with Ga, Al, or In.

4. The electronic apparatus as claimed in claim 1, wherein the zinc oxide layer has a thickness of 150 nm or more.

5. The electronic apparatus as claimed in claim 1, wherein the electronic element is a solar cell element.

6. The electronic apparatus as claimed in claim 1, wherein the electronic element includes a display element.

7. A method of manufacturing an electronic apparatus, including a step of forming a zinc oxide layer on at least one principal surface of a glass base member containing sodium by plasma CVD using an organometallic material.

8. An alkali metal diffusion preventing method, comprising preventing diffusion of alkali metal using a transparent conductive layer.

9. The alkali metal diffusion preventing method according to claim 8, wherein the transparent conductive layer is a zinc oxide layer and the alkali metal is sodium.

10. The alkali metal diffusion preventing method according to claim 9, wherein the zinc oxide layer is formed by plasma CVD using an organometallic material.

11. The alkali metal diffusion preventing method according to claim 10, wherein the zinc oxide layer is formed on a glass substrate containing sodium as the alkali metal.

12. The alkali metal diffusion preventing method according to claim 11, wherein the zinc oxide layer is doped with Ga, Al, or In.
